(19) United States
(12) Patent Application Publication
(10) Pub. No.: US 2023/0390808 A1
(43) Pub. Date: Dec. 7, 2023

(54) DEVICES FOR CLEANING SUBSTRATES AND RELATED METHODS

(71) Applicant: ENTEGRIS, INC., Billerica, MA (US)

(72) Inventors: Subhash Guddati, Singapore (SG); Hyungjun Kim, Gilbert, AZ (US); Aravind Vasanthakumar, Singapore (SG); Thines Kumar Perumal, Singapore (SG); Montray Leavy, Singapore (SG)

(21) Appl. No.: 18/205,265

(22) Filed: Jun. 2, 2023

Related U.S. Application Data
(60) Provisional application No. 63/348,815, filed on Jun. 3, 2022.

(51) Int. Cl. B08B 1/00; B24D 3/00; B24D 18/00

(52) U.S. Cl. CPC B08B 1/002; B24D 3/00; B24D 18/0009

(57) ABSTRACT

A device for cleaning substrates. The device comprises a polymeric pad, a frame body, and a coupling member. The polymeric pad has a top surface and a bottom surface. At least a portion of the frame body extends between the top surface and the bottom surface of the polymeric paid. A coupling member extends upwards from at least a portion of the frame body.

### FIELD

The present disclosure relates to the field of couplable devices for cleaning substrates and related methods.

### BACKGROUND

Chemical mechanical planarization is a process in which substrates are planarized and conditioned via a combination of chemical oxidation and mechanical abrasion. The process of chemical mechanical planarization produces residues, particles, and contaminants.

### SUMMARY

Some embodiments relate to a device. In some embodiments, the device comprises a polymeric pad having a top surface and a bottom surface. In some embodiments, the device comprises a frame body. In some embodiments, at least a portion of the frame body extends between the top surface and the bottom surface of the polymeric pad. In some embodiments, the device comprises a coupling member extending from at least a portion of the frame body.

In some embodiments, the coupling member is configured for coupling the device to an apparatus.

In some embodiments, the coupling member comprises a clamp configured for clamping the device to an apparatus.

In some embodiments, the coupling member comprises a fastener configured for fastening the device to an apparatus.

In some embodiments, the device further comprises a magnet configured for coupling the device to an apparatus.

In some embodiments, the polymeric pad is configured for at least one of cleaning, polishing, or brushing a surface of a semiconductor substrate.

In some embodiments, the polymeric pad comprises a plurality of surface structures extending from the bottom surface of the polymeric pad.

In some embodiments, the plurality of surface structures is integral with the polymeric pad.

In some embodiments, the polymeric pad comprises at least one of a planar bottom surface, a planar top surface, or any combination thereof.

In some embodiments, the polymeric pad comprises a first polymeric material. In some embodiments, the frame body comprises a second polymeric material. In some embodiments, the second polymeric material is different from the first polymeric material.

In some embodiments, the first polymeric material comprises at least one of polyvinyl alcohol, polysulfone, polyether sulfone, polyaryl sulfone, nylon, polyamide, fluoropolymer, polytetrafluoroethylene (PTFE), polyethylene, polypropylene, cellulose, acetate, or any combination thereof.

In some embodiments, the second polymeric material comprises at least one of polypropylene, polyethylene, copolymers thereof, or any combination thereof.

In some embodiments, the polymeric pad has a disc shape.

In some embodiments, the frame body has a disc shape.

In some embodiments, the frame body comprises a plurality of through-holes in a surface of the frame body.

In some embodiments, the frame body and the coupling member are a single unitary structure.

In some embodiments, the polymeric pad is integrally formed with the frame body.

In some embodiments, a diameter of the polymeric pad is 1 mm to 450 mm.

In some embodiments, a porosity of the polymeric pad is 50% to 99%.

Some embodiments relate to a method. In some embodiments, the method comprises obtaining the device according to any of the embodiments disclosed herein in any combination. In some embodiments, the method comprises coupling the device to an apparatus.

In some embodiments, the coupling comprises clamping the device onto a mandrel of the apparatus.

In some embodiments, the coupling comprises fastening the device to a mandrel of the apparatus.

In some embodiments, the coupling comprising securing the device to a mandrel of the apparatus via a magnet(s).

Some embodiments relate to a method for forming a device. In some embodiments, the method comprises obtaining a frame. In some embodiments, the frame comprises a frame body comprising a plurality of through-holes; and a coupling member extending from an edge portion of the frame body. In some embodiments, the method comprises disposing at least the frame body in a mold. In some embodiments, the method comprises obtaining a polymeric material. In some embodiments, the method comprises disposing the polymeric material in the mold. In some embodiments, the method comprises solidifying the polymeric material.

In some embodiments, the method further includes heating the polymeric material to a temperature sufficient to obtain a flowable polymeric material.

In some embodiments, the solidifying comprises cooling the polymeric material to a temperature sufficient to solidify the polymeric material.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 depicts a side view of a non-limiting embodiment of a device which is coupled to a mandrel of an apparatus, according to some embodiments.

FIG. 2 is a sectional view of a non-limiting embodiment of the device depicted in FIG. 1, according to some embodiments.

FIG. 3 is a sectional view of a non-limiting embodiment of a device, according to some embodiments.

FIG. 4A is a sectional view of a non-limiting embodiment of a device, according to some embodiments.

FIG. 4B is a perspective view of a non-limiting embodiment of a pyramid structure, according to some embodiments.

FIG. 5A is a sectional view of a non-limiting embodiment of a device, according to some embodiments.

FIG. 5B is a perspective view of a non-limiting embodiment of a cylindrical pillar, according to some embodiments.

FIG. 5C is a perspective view of a non-limiting embodiment of a square pillar, according to some embodiments.

FIG. 6 is a sectional view of a non-limiting embodiment of a device, according to some embodiments.

FIG. 7 is a sectional view of a non-limiting embodiment of a device, according to some embodiments.

FIG. 8 is a flowchart of a method, according to some embodiments.

FIG. 9 is a flowchart of a method, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.

Some embodiments of the present disclosure relate to devices for cleaning substrates. The devices include a polymeric pad embedded with a frame body, and a coupling member extending upwards from the frame body for securing the device to equipment. The frame body and coupling member are constructed of a material which is generally more rigid than the soft polymeric material which is used to form the polymeric pads. The rigidity of the frame body and coupling member enhances the structural integrity of the polymeric pad, while also replacing the soft polymeric extensions with more rigid coupling members to more securely attach the device to equipment. Additional advantages include easy attachment and detachment from equipment, longer lifetimes of the polymeric pad, improved reliability, among numerous others, which will be apparent based on the disclosure herein.

In some embodiments, the devices disclosed herein are employed for cleaning or brushing substrates, such as silicon wafers, used in semiconductor fabrication. That is, for example, in some embodiments, substrates undergo polishing processes, such as chemical mechanical planarization (CMP) processes, in which chemical oxidation and mechanical abrasion is used to achieve high substrate planarity. Processes, such as CMP, often result in the formation of various residues and contaminants on the surface of the substrate. These residues and contaminants need to be removed prior to being subjected to further semiconductor fabrication processes. Accordingly, the devices disclosed herein may be useful in post-CMP cleaning modules, post-CMP pre-cleaning modules, and the like.

As used herein, the term “residue” refers to particles generated during a process(es). The term includes “post-CMP residue(s).” A post-CMP residue may include, for example and without limitation, particles from a polishing slurry, such as, for example and without limitation, at least one of silica-containing particles, chemicals in the polishing slurry, reaction by-products of the polishing slurry, carbon-rich particles, polishing pad particles, brush deloading particles, metals (e.g., at least one of copper, aluminum, tungsten, or any combination thereof), metal oxides, organic residues, barrier layer residues, any other materials that are the by-products of the CMP process, or any combination thereof. It will be appreciated that the term may include other types of residues without departing from the scope of this disclosure.

As used herein, the term “contaminant” refers to an undesirable substance(s). The term includes, for example and without limitation, at least one of chemicals in the CMP slurry, reaction by-products of the polishing slurry, any other materials which are by-products of the CMP process, or any combination thereof. An example of a contaminant includes benzotriazole. It will be appreciated that the term may include other types of contaminants without departing from the scope of this disclosure.

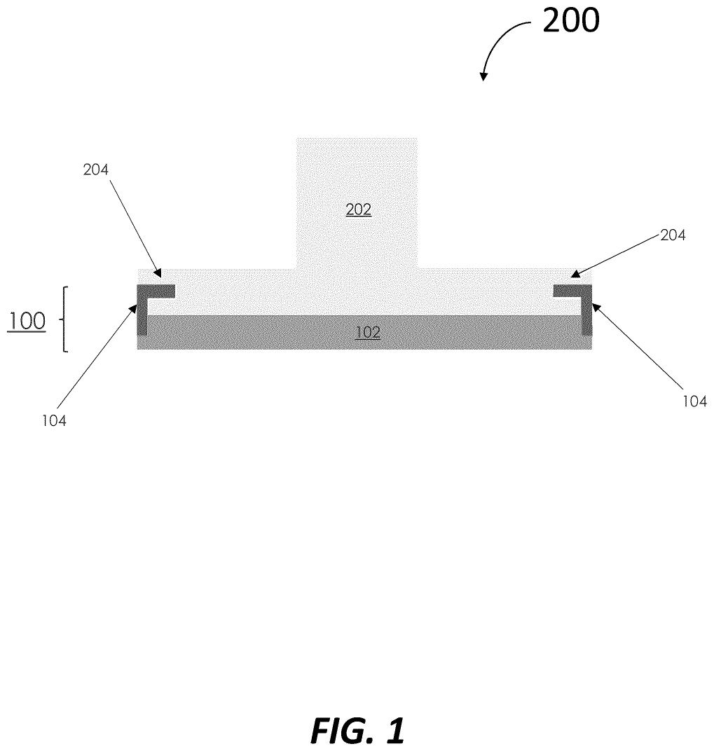

FIG. 1 depicts a side view of a non-limiting embodiment of a device 100 which is coupled to a mandrel 202 of an apparatus 200. The device 100 may include a device according to any of the embodiments disclosed herein in any combination. In the illustrated embodiment, the device 100 includes a polymeric pad 102 configured for contacting (e.g., cleaning, brushing, polishing, etc.) a substrate surface. Coupling members 106, which are shown extending upwards from a frame body (not depicted), are configured for coupling the device 100 to the apparatus 200. In some embodiments, the coupling members 106 are configured to be pulled apart sufficient to couple the device 100 to the mandrel 202, while also being sufficiently resilient to snap back and secure the device 100 to the mandrel 202. In some embodiments, the mandrel 202 may further include grooves 204, as shown, to further secure the device 100 to the apparatus.

Although the side view depicts coupling members 106, in some embodiments, the device 100 includes a single coupling member. In some embodiments, the device 100 includes a plurality of coupling members. In some embodiments, the polymeric pad 102 is formed in the shape of a disc, with the coupling member extending upwards from a periphery or outer perimeter of the disc. In some of these embodiments, the coupling member may extend around all or a portion of the outer perimeter of the disc.

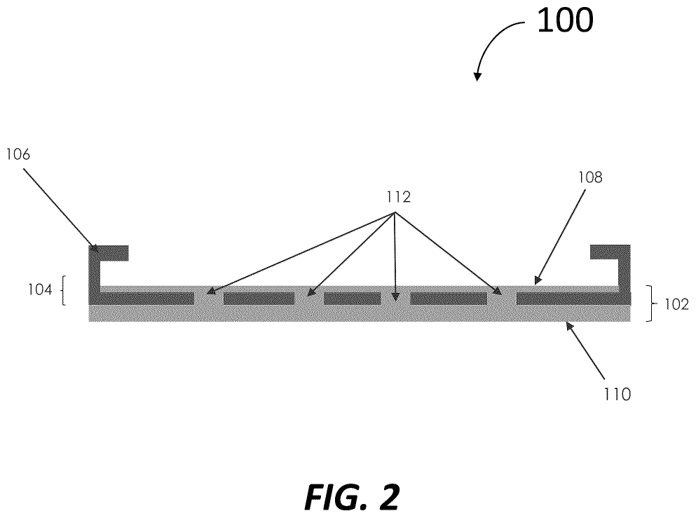

FIG. 2 is a sectional view of a non-limiting embodiment of the device 100, according to some embodiments. The device 100 includes a polymeric pad 102, a frame body 104, and a coupling member 106. The polymeric pad 102 has a top surface 108 and a bottom surface 110. The coupling member 106 is integral with the frame body 104. That is, the coupling member 106 and the frame body are a single unitary structure, formed of the same material of construction. As the polymeric pad 102 is generally formed of a comparatively softer polymeric material (e.g., polyvinyl alcohol, etc.) for cleaning substrates, the frame body 104 is generally disposed within the polymeric pad 102 so as to provide structural rigidity to the device 100. That is, the frame body 104 extends through the polymeric pad 102, between the top surface 108 and the bottom surface 110. In addition, the frame body 104 includes through-holes 112 in a surface of the frame body 104. The through-holes 112 permit, during fabrication of the device 100, a flowable polymeric material to be disposed in the through-holes, as well as above and below the frame body 104, such that, when the flowable polymeric material is solidified, the resulting polymeric pad 102 is integrally formed with at least the frame body 104. The coupling member 106 extends upwards from a periphery of the frame body 104, above the polymeric pad 102, for coupling the device 100 to the apparatus 200.

The polymeric pad 102 generally includes a material which is softer than the frame body 104 and the coupling member 106. For example, in some embodiments, the polymeric pad includes a soft polymeric material, such as polyvinyl alcohol. In some embodiments, the polymeric pad comprises at least one of polysulfone, polyether sulfone, polyaryl sulfone, nylon, polyamide, fluoropolymer, polytetrafluoroethylene (PTFE), polyethylene, polypropylene, cellulose, acetate, or any combination thereof. In some embodiments, the frame body 104, the coupling member 106, or any combination thereof includes a more rigid polymeric material, such as, at least one of polypropylene, polyethylene, any copolymer thereof, or any combination thereof. In some embodiments, the frame body 104, the coupling member 106, or any combination thereof includes a flowable polymeric material which, once solidified, results in the coupling member 106 being sufficiently resilient such that the coupling member 106 can be flexed, while also being sufficiently tensile to bias the clamp inwardly sufficient to engage the apparatus 200 (e.g., snap on and/or snap off a mandrel).

The polymeric pad 102 may have a thickness in a range of 0.1 mm to 50 mm, or any range or subrange between 0.1 mm and 50 mm. In some embodiments, for example, the polymeric pad 102 has a thickness in a range of 1 mm to 10 mm, 1 mm to 9 mm, 1 mm to 8 mm, 1 mm to 7 mm, 1 mm to 6 mm, 1 mm to 5 mm, 1 mm to 4 mm, 1 mm to 3 mm, 1 mm to 2 mm, 2 mm to 10 mm, 3 mm to 10 mm, 4 mm to 10 mm, 5 mm to 10 mm, 6 mm to 10 mm, 7 mm to 10 mm, 8 mm to 10 mm, 9 mm to 10 mm, 2 mm to 7 mm, 2 mm to 6 mm, 2 mm to 5 mm, 2 mm to 4 mm, 3 mm to 7 mm, 4 mm to 7 mm, 5 mm to 7 mm, 6 mm to 7 mm, any range or subrange therebetween, or any combination thereof.

A diameter of the polymeric pad 102 may range from 1 mm to 450 mm, or any range or subrange between 1 mm and 450 mm. In some embodiments, for example, the polymeric pad 102 has a thickness in a range of 1 mm to 25 mm, 1 mm to 50 mm, 1 mm to 75 mm, 1 mm to 100 mm, 1 mm to 125 mm, 1 mm to 150 mm, 1 mm to 200 mm, 1 mm to 300 mm, 1 mm to 450 mm, 25 mm to 450 mm, 50 mm to 450 mm, 75 mm to 450 mm, 100 mm to 450 mm, 125 mm to 450 mm, 150 mm to 450 mm, 200 mm to 450 mm, or 300 mm to 450 mm.

In some embodiments, the diameter of the polymeric pad 102 is less than a diameter of a substrate. In some embodiments, the substrate is a silicon wafer. In some embodiments, the diameter of the polymeric pad 102 is less than 25 mm (e.g., 1 mm to 24 mm), less than 51 mm (e.g., 1 mm to 50 mm), less than 76 mm (e.g., 1 mm to 75 mm), less than 100 mm (e.g., 1 mm to 99 mm), less than 125 mm (e.g., 1 mm to 124 mm), less than 150 mm (e.g., 1 mm to 149 mm), less than 200 mm (e.g., 1 mm to 199 mm), less than 300 mm (e.g., 1 mm to 299 mm), or less than 450 mm (1 mm to 449 mm).

A porosity of the polymeric pad 102 may refer to a dimensionless ratio of the volume of void space to the volume of bulk material. In some embodiments, the porosity of the polymeric pad 102 is 50% to 99%, or any range or subrange between 50% and 99%. In some embodiments, the porosity of the polymeric pad 102 is 60% to 99%, 65% to 99%, 70% to 99%, 75% to 99%, 80% to 99%, 85% to 99%, 90% to 99%, 85% to 95%, 85% to 90%, or 90% to 95%.

The coupling member 106 may obviate the need for the polymeric pad 102 to have any extension configured to be inserted into the mandrel 202 to secure the device 100 to the apparatus 200. For example, while conventional polymeric pads have, on the top surface of the polymeric pad, dovetail structures which couple the conventional polymeric pad to an apparatus, the polymeric pad 102 disclosed herein does not include any structure for coupling the polymeric pad 102 to the apparatus 200. That is, in some embodiments, the polymeric pad 102 has a planar top surface. In some embodiments, the polymeric pad 102 has a non-planar top surface, wherein the non-planar top surface does not comprise any structure for coupling the polymeric pad 102 to the apparatus 200.

The polymeric pad 102 has a bottom surface configured for cleaning, polishing, or brushing a substrate surface. In some embodiments, the polymeric pad 102 has a planar bottom surface. In some embodiments, the polymeric pad 102 has a non-planar bottom surface. For example, in some embodiments, the polymeric pad 102 includes a plurality of surface structures extending from the bottom surface of the polymeric pad 102. Various embodiments of the surface structures are described below.

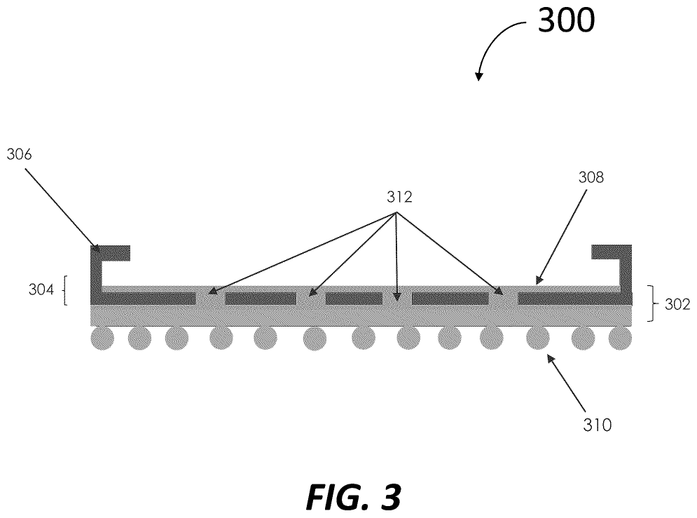

FIG. 3 is a sectional view of a non-limiting embodiment of a device 300, according to some embodiments. The device 300 is similar to the device 100. Accordingly similar reference numbers are used. The device 300 includes a plurality of surface structures 320. The plurality of surface structures 320 is integral with the polymeric pad 302 and extend downwards from the bottom surface 310 of the polymeric pad 302. The plurality of surface structures 320 is configured for cleaning a substrate surface. As shown in FIG. 3, the plurality of surface structures 320 has a circular cross-section.

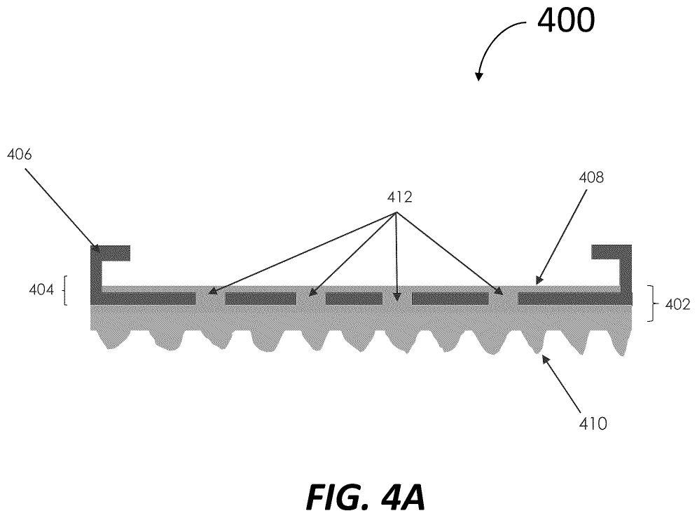

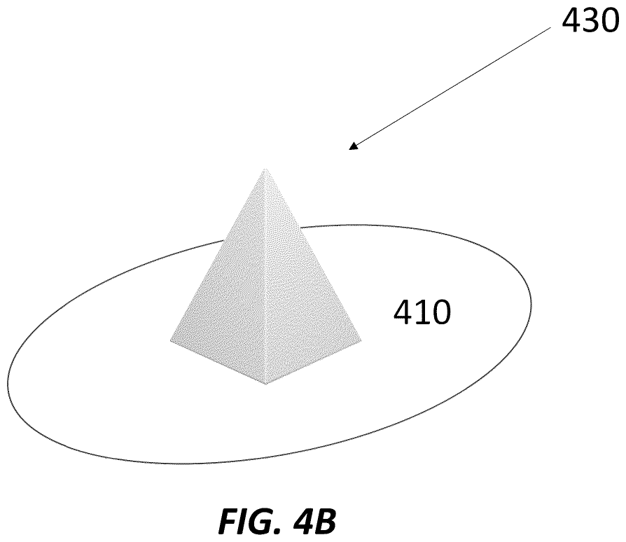

FIG. 4 is a sectional view of a non-limiting embodiment of a device 400, according to some embodiments. The device 400 is similar to the device 100. Accordingly similar reference numbers are used. The device 400 includes a plurality of surface structures 420. The plurality of surface structures 420 is integral with the polymeric pad 402 and extend downwards from the bottom surface 410 of the polymeric pad 402. The plurality of surface structures 420 is configured for cleaning a substrate surface. As shown in FIG. 4, the plurality of surface structures 420 has a triangular cross-section. In some embodiments, the plurality of surface structures 420 comprises a plurality of pyramid structures, such as the pyramid structure 430 as shown in FIG. 4B, extending from the bottom surface 410.

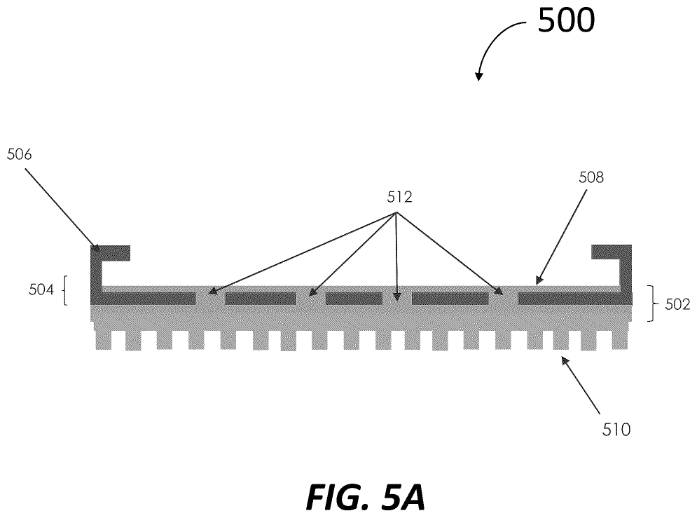

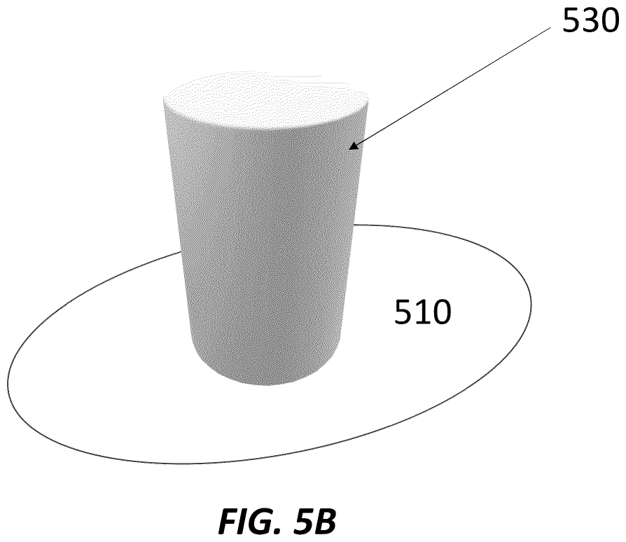

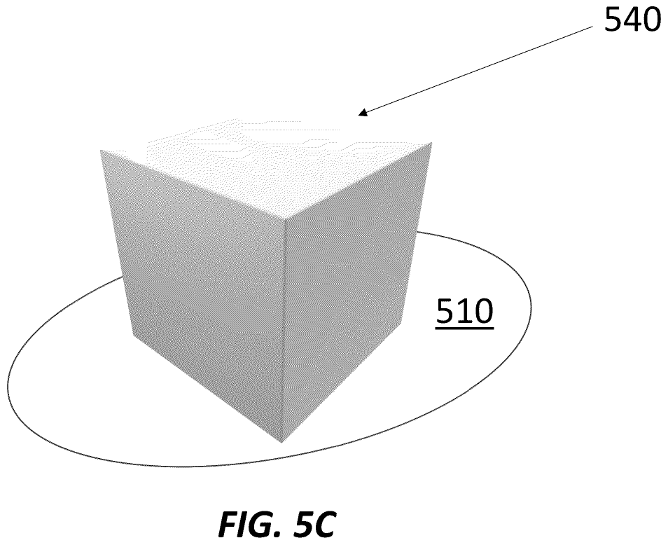

FIG. 5A is a sectional view of a non-limiting embodiment of a device 500, according to some embodiments. The device 500 is similar to the device 100. Accordingly similar reference numbers are used. The device 500 includes a plurality of surface structures 520. The plurality of surface structures 520 is integral with the polymeric pad 502 and extend downwards from the bottom surface 510 of the polymeric pad 502. The plurality of surface structures 520 is configured for cleaning a substrate surface. As shown in FIG. 5A, the plurality of surface structures 520 has a rectangular (or quadrilateral) cross-section. In some embodiments, for example, the plurality of surface structures 520 comprises a plurality of cylindrical pillars, such as the cylindrical pillar 530 shown in FIG. 5B, extending from the bottom surface 510. In some embodiments, the plurality of surface structures 520 comprises a plurality of square pillars, such as the square pillar 540 shown in FIG. extending from the bottom surface 510.

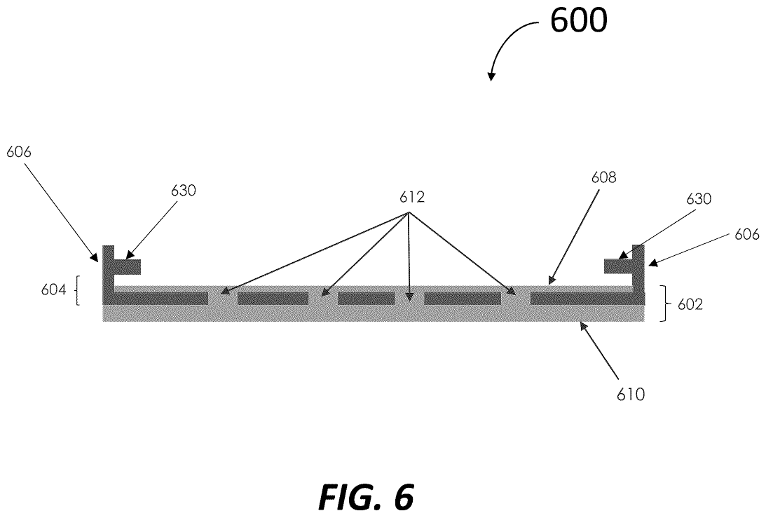

FIG. 6 is a sectional view of a non-limiting embodiment of a device 600, according to some embodiments. The device 600 is similar to the device 100. Accordingly similar reference numbers are used. The device 600 includes coupling members 606. Each of the coupling members 606 is configured to fasten the device 600 to an apparatus. In the illustrated embodiment, each of the coupling members 606 is shown including a fastener 630, such as, for example a mechanical fastener (e.g., a screw, etc.), for fastening the device 600 to an apparatus. In some embodiments, each fastener 630 is configured to be passed through the coupling member 606 to a receiving member in the apparatus which receives the fastener 630 and couples the device 600 to the apparatus.

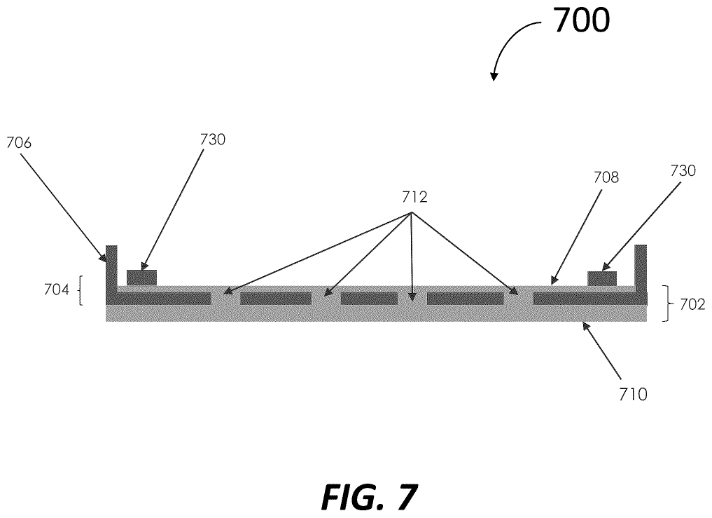

FIG. 7 is a sectional view of a non-limiting embodiment of a device 700, according to some embodiments. The device 700 is similar to the device 100. Accordingly similar reference numbers are used. The device 700 includes at least one magnet 730 coupled to the top surface 708 of the polymeric pad 702. The location and arrangement of the at least one magnet 730 on the top surface 708 of the polymeric pad 702 is not particularly limited. In some embodiments, the at least one magnet 730 is a single magnet which curves around the outer perimeter of a disc-shaped polymeric pad 702. For each of the various configurations of the at least one magnet 730, the apparatus comprises at least one second magnet for coupling the device 700 to the apparatus by magnetism.

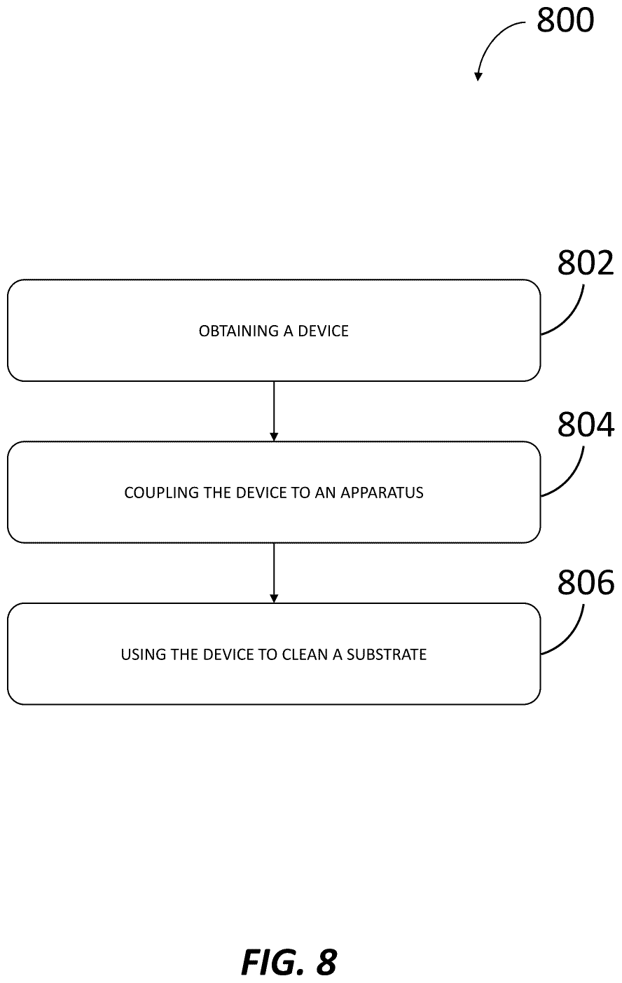

FIG. 8 is a flowchart of a method 800, according to some embodiments. The method includes a step 802 of obtaining a device according to any of the embodiments disclosed herein in any combination. The method includes a step 804 of coupling the device to an apparatus. The device may be coupled according to any of the embodiments disclosed herein in any combination. For example, the device may be clamped (e.g., snapped on) to the apparatus, fastened to the apparatus, coupled to the apparatus via magnets, or any combination thereof. In some embodiments, the method further includes a step 806 of using the device to clean a substrate. The method may include any one or more of the foregoing steps which may be performed in any order.

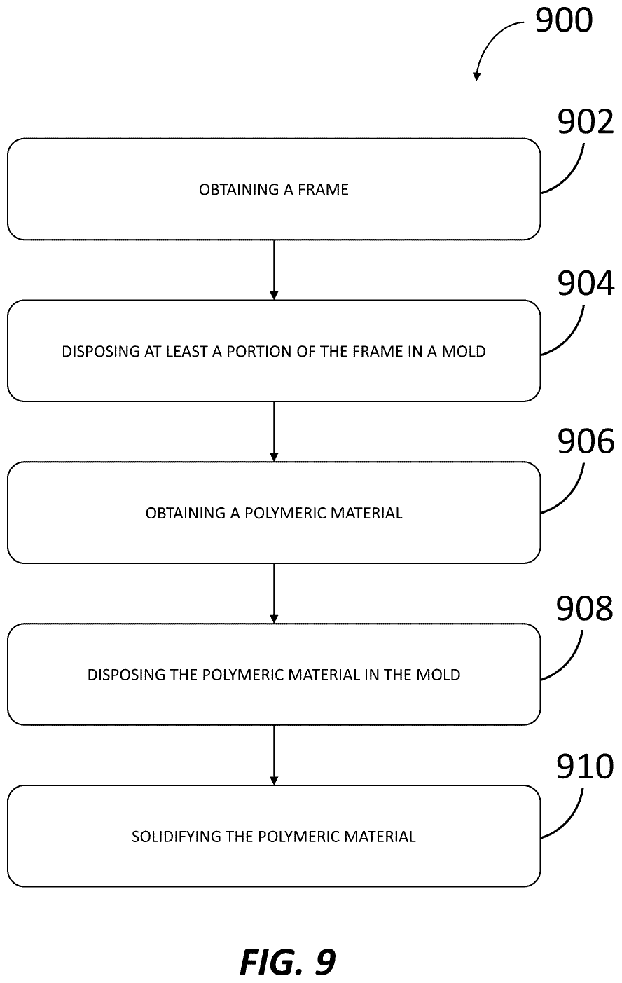

FIG. 9 is a flowchart of a method for forming a device, according to some embodiments. The method 900 includes a step 902 of obtaining a frame including a frame body and a coupling member. The frame may include a frame body according to any of the embodiments disclosed herein in any combination and a coupling member according to any of the embodiments disclosed herein in any combination. In some embodiments, the frame body includes a plurality of through-holes in a surface of the frame body, and the coupling member extends from an edge portion of the frame body. The method then includes a step 904 of disposing at least the frame body in a mold. The method further includes a step 906 of obtaining a polymeric material (e.g., a flowable polymeric material) and a step of 908 disposing the polymeric material in the mold. The method then includes a step of 910 solidifying the polymeric material (e.g., sufficient to form a device according to any of the embodiments disclosed herein in any combination). In some embodiments, the method further includes heating the polymeric material to a temperature sufficient to obtain a flowable polymeric material. In some embodiments, the solidifying includes cooling the polymeric material to a temperature sufficient to solidify the polymeric material. The method may include any one or more of the foregoing steps which may be performed in any order.

ASPECTS

Various Aspects are described below. It is to be understood that any one or more of the features recited in the following Aspect(s) can be combined with any one or more other Aspect(s).
Aspect 1. A device comprising:
   a polymeric pad having a top surface and a bottom surface;
   a frame body,
      wherein at least a portion of the frame body extends between the top surface and the bottom surface of the polymeric pad; and
   a coupling member extending from at least a portion of the frame body.
Aspect 2. The device according to aspect 1, wherein the coupling member is configured for coupling the device to an apparatus.
Aspect 3. The device according to any one of aspects 1-2, wherein the coupling member comprises a clamp configured for clamping the device to an apparatus.
Aspect 4. The device according to any one of aspects 1-3, wherein the coupling member comprises a fastener configured for fastening the device to an apparatus.
Aspect 5. The device according to any one of aspects 1-4, further comprising a magnet configured for coupling the device to an apparatus.
Aspect 6. The device according to any one of aspects 1-5, wherein the polymeric pad is configured for at least one of cleaning, polishing, or brushing a surface of a semiconductor substrate.
Aspect 7. The device according to any one of aspects 1-6, wherein the polymeric pad comprises a plurality of surface structures extending from the bottom surface of the polymeric pad.
Aspect 8. The device according to aspect 7, wherein the plurality of surface structures is integral with the polymeric pad.
Aspect 9. The device according to any one of aspects 1-8, wherein the polymeric pad comprises at least one of a planar bottom surface, a planar top surface, or any combination thereof.
Aspect 10. The device according to any one of aspects 1-9,
   wherein the polymeric pad comprises a first polymeric material,
   wherein the frame body comprises a second polymeric material,
      wherein the second polymeric material is different from the first polymeric material.
Aspect 11. The device according to aspect 10, wherein the first polymeric material comprises at least one of polyvinyl alcohol, polysulfone, polyether sulfone, polyaryl sulfone, nylon, polyamide, fluoropolymer, polytetrafluoroethylene (PTFE), polyethylene, polypropylene, cellulose, acetate, or any combination thereof.
Aspect 12. The device according to aspect 10, wherein the second polymeric material comprises at least one of polypropylene, polyethylene, copolymers thereof, or any combination thereof.
Aspect 13. The device according to any one of aspects 1-12, wherein the polymeric pad has a disc shape.
Aspect 14. The device according to any one of aspects 1-13, wherein the frame body has a disc shape.
Aspect 15. The device according to any one of aspects 1-14, wherein the frame body comprises a plurality of through-holes in a surface of the frame body.
Aspect 16. The device according to any one of aspects 1-15, wherein the frame body and the coupling member are a single unitary piece.
Aspect 17. The device according to any one of aspects 1-16, wherein the polymeric pad is integrally formed with the frame body.
Aspect 18. The device according to any one of aspects 1-17, wherein a diameter of the polymeric pad is 1 mm to 450 mm.
Aspect 19. The device according to any one of aspects 1-18, wherein a porosity of the polymeric pad is 50% to 99%.
Aspect 20. A method comprising:
   obtaining the device according to any one of aspects 1-19; and
   coupling the device to an apparatus.
Aspect 21. The method according to aspect 20, wherein the coupling comprises clamping the device onto a mandrel of the apparatus.
Aspect 22. The method according to any one of aspects 20-21, wherein the coupling comprises fastening the device to a mandrel of the apparatus.
Aspect 23. The method according to any one of aspects 20-22, wherein the coupling comprising securing the device to a mandrel of the apparatus via magnets.
Aspect 24. A method for forming a device, comprising:
   obtaining a frame,
      wherein the frame comprises:
         a frame body comprises a plurality of through-holes; and
         a coupling member extending from an edge portion of the frame body,
   disposing at least the frame body in a mold;
   obtaining a polymeric material;
   disposing the polymeric material in the mold; and
   solidifying the polymeric material sufficient to form the device according to any one of aspects 1-17.
Aspect 25. The method according to aspect 24, further comprising heating the polymeric material to a temperature sufficient to obtain a flowable polymeric material.
Aspect 26. The method according to any one of aspects 24-25, wherein the solidifying comprises cooling the polymeric material to a temperature sufficient to solidify the polymeric material.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A device comprising:
a polymeric pad having a top surface and a bottom surface;
a frame body,
wherein at least a portion of the frame body extends between the top surface and the bottom surface of the polymeric pad; and
a coupling member extending from at least a portion of the frame body.

2. The device of claim 1, wherein the coupling member is configured for coupling the device to an apparatus.

3. The device of claim 1, wherein the coupling member comprises a clamp configured for clamping the device to an apparatus.

4. The device of claim 1, wherein the coupling member comprises a fastener configured for fastening the device to an apparatus.

5. The device of claim 1, further comprising a magnet configured for coupling the device to an apparatus.

6. The device of claim 1, wherein the polymeric pad is configured for at least one of cleaning, polishing, or brushing a surface of a semiconductor substrate.

7. The device of claim 1, wherein the polymeric pad comprises a plurality of surface structures extending from the bottom surface of the polymeric pad.

8. The device of claim 7, wherein the plurality of surface structures is integral with the polymeric pad.

9. The device of claim 1, wherein the polymeric pad comprises at least one of a planar bottom surface, a planar top surface, or any combination thereof.

10. The device of claim 1,
wherein the polymeric pad comprises a first polymeric material,
wherein the frame body comprises a second polymeric material,
wherein the second polymeric material is different from the first polymeric material.

11. The device of claim 10, wherein the first polymeric material comprises at least one of polyvinyl alcohol, polysulfone, polyether sulfone, polyaryl sulfone, nylon, polyamide, fluoropolymer, polytetrafluoroethylene (PTFE), polyethylene, polypropylene, cellulose, acetate, or any combination thereof.

12. The device of claim 10, wherein the second polymeric material comprises at least one of polypropylene, polyethylene, copolymers thereof, or any combination thereof.

13. The device of claim 1, wherein the polymeric pad has a disc shape.

14. The device of claim 1, wherein the frame body has a disc shape.

15. The device of claim 1, wherein the frame body comprises a plurality of through-holes in a surface of the frame body.

16. The device of claim 1, wherein the frame body and the coupling member are a single unitary structure.

17. The device of claim 1, wherein the polymeric pad is integrally formed with the frame body.

18. The device of claim 1, wherein a diameter of the polymeric pad is 1 mm to 450 mm.

19. The device of claim 1, wherein a porosity of the polymeric pad is 50% to 99%.

20. A method comprising:
obtaining the device according to claim 1; and
coupling the device to an apparatus.

21. The method of claim 18, wherein the coupling comprises clamping the device onto a mandrel of the apparatus.

22. The method of claim 18, wherein the coupling comprises fastening the device to a mandrel of the apparatus.

23. The method of claim 18, wherein the coupling comprising securing the device to a mandrel of the apparatus via magnets.

24. A method for forming a device, comprising:
obtaining a frame,
wherein the frame comprises:
a frame body comprises a plurality of through-holes; and
a coupling member extending from an edge portion of the frame body,
disposing at least the frame body in a mold;
obtaining a polymeric material;
disposing the polymeric material in the mold; and
solidifying the polymeric material sufficient to form the device according to claim 1.

25. The method of claim 22, further comprising heating the polymeric material to a temperature sufficient to obtain a flowable polymeric material.

26. The method of claim 22, wherein the solidifying comprises cooling the polymeric material to a temperature sufficient to solidify the polymeric material.
